(19) United States
(12) Patent Application Publication
(10) Pub. No.: US 2015/0129022 A1
(43) Pub. Date: May 14, 2015

(54) BACK CONTACT SOLAR CELL

(71) Applicant: NEO SOLAR POWER CORP., Hsinchu (TW)

(72) Inventors: Chorngjye HUANG, Hsinchu (TW); Feng-Yu YANG, Hsinchu (TW); Shan-Chuang PEI, Hsinchu (TW); Ching-Chun YEH, Hsinchu (TW); Tien-Shao CHUANG, Hsinchu (TW)

(21) Appl. No.: 14/313,564

(22) Filed: Jun. 24, 2014

(30) Foreign Application Priority Data
Nov. 11, 2013 (TW) 102140884

(51) Int. Cl. H01L 31/075; H01L 31/065; H01L 31/0224

(52) U.S. Cl. CPC H01L 31/075; H01L 31/022441; H01L 31/065
USPC 136/255

(57) ABSTRACT

A back contact solar cell includes a solar cell substrate, an intrinsic layer, a second conductive type semiconductor layer and an electrode layer. The solar cell substrate includes a substrate body doped with a first conductive type semiconductor and a plurality of first conductive type semiconductor doped regions. The first conductive type semiconductor doped region is formed on a back side of the substrate body. The intrinsic layer is formed on the back side, and includes a plurality of first openings to expose the first conductive type semiconductor doped regions. The second conductive type semiconductor layer is deposited on the intrinsic layer, and includes a plurality of second openings correspond the first openings. The electrode layer includes a plurality of first electrode regions and a second electrode region. The first electrode regions are disposed on the first conductive type semiconductor doped regions. The second electrode regions are disposed on the second conductive type semiconductor layer, and separated with the first electrode regions.

### FIELD OF THE INVENTION

The present invention relates to a back contact solar cell, and more particularly relates to a back contact solar cell having an intrinsic layer and a second conductive type semiconductor layer deposited on a substrate body doped with a first conductive type semiconductor material.

### BACKGROUND OF THE INVENTION

Due to the supply issue of oil and the greenhouse gas emission, solar cell development has accelerated because solar energy is the sustainable energy. The most common solar cell includes a silicon wafer doped with P-type semiconductor and N-type semiconductor to form the PN junction. When the solar cell is illuminated by sunlight to generate electron-hole pairs, the electric field created on the PN junction promotes charge flow to separate the electrons and holes, which are further directed by the external circuitry connected to the electrodes.

However, the solar cells in present usually have the two electrodes located on the front surface and the back surface of the solar cell respectively. The electrode on the front surface may shield the light-absorbing surface area of the solar cell to affect light absorption and degrade the conversion efficiency. To prevent the light-absorbing surface of the solar cell from being shielded by the electrode, the back contact solar cell is created.

FIG. 1 is a cross-section view of a conventional back contact solar cell. FIG. 2 is a cross-section view of a conventional back contact solar cell with hetero-junction. As shown, the structure of the back contact solar cell PA100 includes a cell body PAL a plurality of first electrodes PA2, and a plurality of second electrodes PA3. A plurality of first conductive type semiconductor doped regions PA12 and second conductive type semiconductor doped regions PA13 are alternatively arrayed on the back side PA11 of cell body PA1. The first electrode PA2 and the second electrode PA3 are electrically connected to the first conductive type semiconductor doped regions PA12 and the second conductive type semiconductor doped regions PA13 respectively, and a dielectric layer PA4 is interposed between the first electrode PA2 and the second electrode PA3. It is noted that the front side (i.e. the light absorbing surface) of the cell body PA1 should not be shielded by the first electrode PA2 and the second electrode PA3 to increase the amount of light being absorbed by the solar cell.

Among the various back contact solar cells, to further suppress recombination of electrons and holes on the PN junction, to reduce surface recombination velocity, and to enhance open-circuit voltage, the back contact solar cell with hetero-junction has been disclosed in prior art, such as Taiwan patent publication number 201322465, which describes a solar cell PA200 includes a second conductive type doped region PA112 located in the first conductive type silicon substrate PA102 below the second conductive type semiconductor layer PA110. The first conductive type silicon substrate PA102 has an intrinsic semiconductor layer PA106 on the surface thereof, and the second conductive type semiconductor layer PA110 is located on the intrinsic semiconductor layer PA106 such that a hetero-junction is directly formed by generating the second conductive type doped region PA112 in the first conductive type semiconductor substrate PA102. However, because the described intrinsic semiconductor layer PA106 is an amorphous semiconductor layer, the resistance is higher than the conventional metal materials. The first conductive type semiconductor layer PA108 acting as the back surface field (BSF) is located on the intrinsic semiconductor layer PA106. The BSF is much weaker than the emitter field, so the intrinsic semiconductor layer PA106 may degrade the ability of carrier conduction. Moreover, the problem of too many layers and interfaces between the first conductive type silicon substrate PA102 and the second conductive type semiconductor layer PA110 would degrade the conversion efficiency.

### BRIEF SUMMARY OF INVENTION

In view of the prior art, it is noted that the conventional back contact solar cell introduces the intrinsic semiconductor layer to suppress recombination of electrons and holes on the PN junction, reduce surface recombination velocity, and enhance open-circuit voltage, however, the ability of carrier conduction would be degraded because the intrinsic layer is a high resistance material. In addition, the problem is that too many defects formed in the interfaces between the first conductive type silicon substrate and the second conductive type semiconductor layer and it would degrade the conversion efficiency.

As mentioned, a back contact solar cell is provided in the present invention, which includes a solar cell substrate, an intrinsic layer, a second conductive type semiconductor layer, and an electrode layer. The solar cell substrate includes a substrate body and a plurality of first conductive type semiconductor doped regions. The substrate body has a front side and a back side opposite to the front side, and is doped with a first conductive type semiconductor of a first doping concentration. The plurality of first conductive type semiconductor doped regions are spaced apart and formed on the back side of the substrate body. The first conductive type semiconductor doped region is doped with the first conductive type semiconductor of a second doping concentration, and the second doping concentration is greater than the first doping concentration.

The intrinsic layer is formed on the back side of the substrate body and on the first conductive type semiconductor doped regions, and the intrinsic layer has a plurality of first openings to expose the first conductive type semiconductor doped regions.

The second conductive type semiconductor layer is formed on the intrinsic layer, and has a plurality of second openings corresponding to the first openings, and a width of the second opening is not smaller than that of the corresponding first opening.

The electrode layer includes a plurality of first electrode regions and a plurality of second electrode regions. The plurality of first electrode regions are electrically connected to the first conductive type semiconductor doped region through the first openings and separated from the second conductive type semiconductor layer. The plurality of second electrode regions are spaced apart and formed on the second conductive type semiconductor layers and separated from the first electrode regions.

As mentioned, in comparison with the back contact solar cell of prior art, which has the p-n junction formed in the conductive silicon substrate and adopts the intrinsic layer merely as a passivation layer. A second conductive type semiconductor layer is formed on the intrinsic layer, therefore, the substrate body with the first conductive type semiconductor material, the intrinsic layer and the second conductive type semiconductor layer form a p-i-n hetero-junction. The present invention uses the intrinsic layer as a passivation layer for the back side of the substrate body, it prevents the formation of defects in the interfaces of junction.

In addition, the first electrode region of the present invention electrically connected to the first conductive type semiconductor doped region via the first openings of the intrinsic layer, and the resistance can be reduced effectively.

In accordance with an embodiment of the present invention, the area size of the first openings is not greater than the area size of the first conductive type semiconductor doped regions, wherein the area size of the first opening is from 0.2% to 100% of the area size of the first conductive type semiconductor doped region. As a preferred embodiment, the area size of the first opening is from 0.35% to 70% of the area size of the first conductive type semiconductor doped region.

In accordance with an embodiment of the present invention, the area size of the first openings is greater than the area size of the first conductive type semiconductor doped regions. As a preferred embodiment, the back contact solar cell further comprises a plurality of passivation layers formed in the first openings respectively, each of the passivation layers has a third opening, the first electrode regions are electrically connected to the first conductive type semiconductor doped regions through the third openings respectively, and the area size of the third openings is not greater than the area size of the first conductive type semiconductor doped regions. In addition, the first conductive type semiconductor doped regions are partially covered by the passivation layers respectively and the first conductive type semiconductor doped regions partially exposed through the third openings of the passivation such that the first electrode region is electrically connected to the first conductive type semiconductor doped region through the third opening. The area size of the third opening is from 0.2% to 100% of the area size of the first conductive type semiconductor doped region, and it is preferred that the area size of the third opening is from 0.35% to 70% of the area size of the first conductive type semiconductor doped region. Moreover, in the other embodiment, the neighboring first electrode regions and the neighboring intrinsic layer are separated by a gap, and the back contact solar cell further comprises a plurality of passivation layers deposited in the gap between the first electrode region and the intrinsic layer.

In accordance with an embodiment of the present invention, the third openings are formed in a circular shape, a strip shape, or a combination thereof.

In accordance with an embodiment of the present invention, the solar cell substrate further comprises a front surface field layer, formed on the front side. As a preferred embodiment, the front surface field layer is doped with the first conductive type semiconductor of a third doping concentration, which is greater than the first doping concentration.

In accordance with an embodiment of the present invention, the substrate body has a textured surface on the front side.

In accordance with an embodiment of the present invention, the first openings are formed in a circular shape, of a strip shape, or a combination thereof.

In accordance with an embodiment of the present invention, the second openings are formed in a strip shape.

In accordance with an embodiment of the present invention, the intrinsic layer is an amorphous silicon intrinsic layer or a microcrystal silicon intrinsic layer.

In accordance with an embodiment of the present invention, the second conductive type semiconductor layer is an amorphous silicon second conductive type semiconductor layer or a microcrystal silicon second conductive type semiconductor layer.

The embodiments adopted in the present invention would be further discussed by using the following paragraph and the figures for a better understanding.

### BRIEF DESCRIPTION OF THE DRAWINGS

FIG. 1 is a cross-section view of a conventional back contact solar cell.

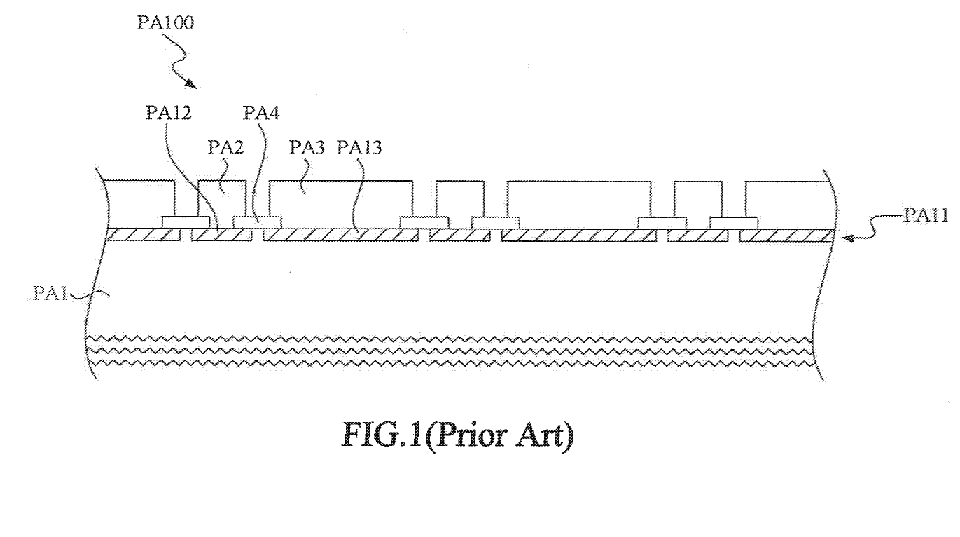

FIG. 2 is a cross-section view of a conventional back contact solar cell with hetero-junction.

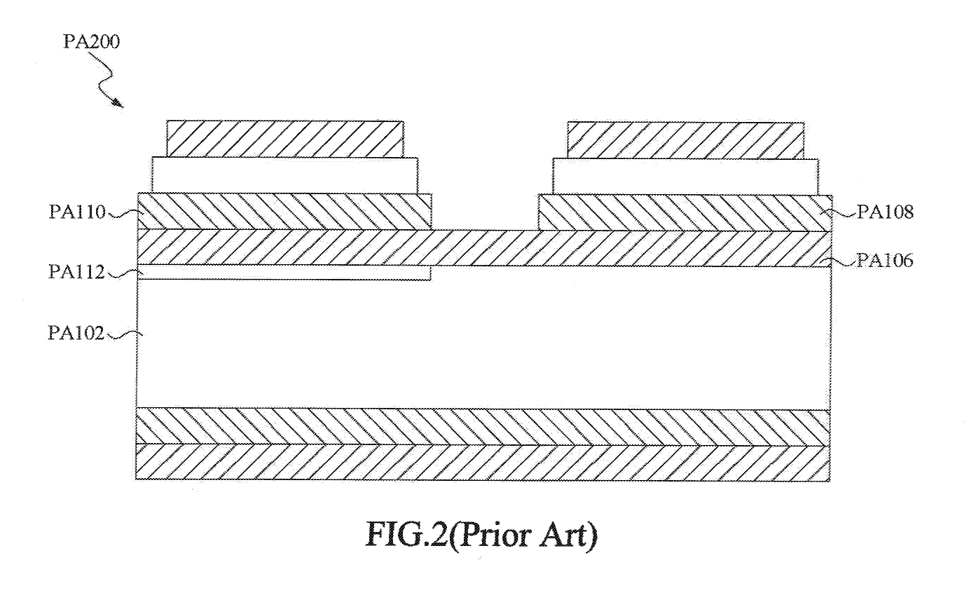

FIG. 3 is a cross-section view showing a back contact solar cell in accordance with a first preferred embodiment of the present invention.

FIG. 4 is a 3D cross-section view of a back contact solar cell in accordance with the first preferred embodiment of the present invention.

FIG. 5 is a top view of a back contact solar cell in accordance with a second preferred embodiment of the present invention.

FIG. 6 is a cross-section view showing a back contact solar cell in accordance with a third preferred embodiment of the present invention.

FIG. 7 is a diagram showing the relationship of conversion efficiency of the back contact solar cell of the present invention and the opening size by percentage.

FIG. 8 is a diagram showing the relationship of conversion efficiency of the back contact solar cell of the present invention and the opening size by percentage as the percentage is between 0.1% and 10%.

### DETAILED DESCRIPTION OF THE INVENTION

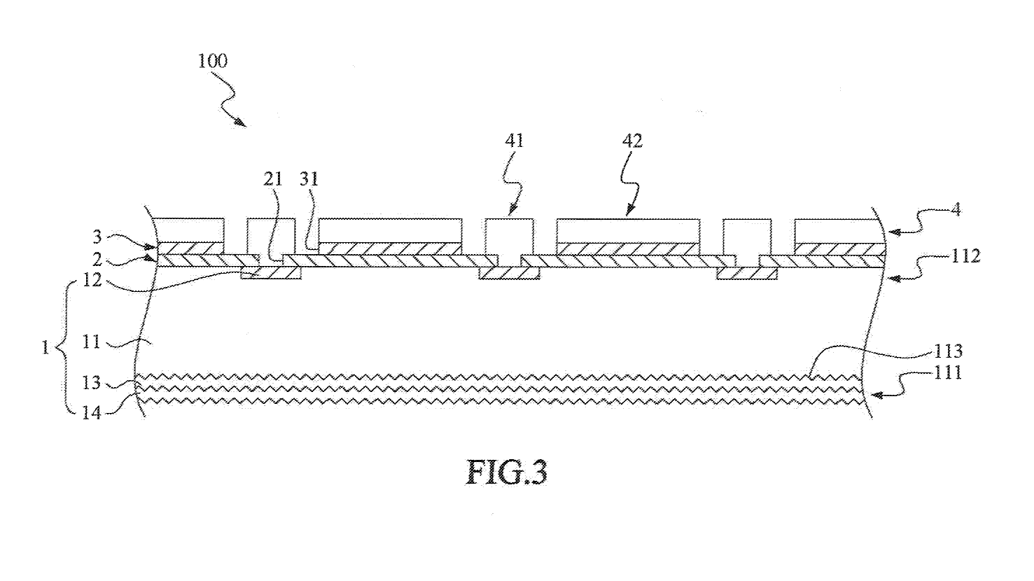

FIG. 3 is a cross-section view showing a back contact solar cell in accordance with a first preferred embodiment of the present invention.

As shown, the back contact solar cell 100 includes a solar cell substrate 1, an intrinsic layer 2, a second conductive type semiconductor layer 3, and an electrode layer 4.

The solar cell substrate 1 includes a substrate body 11, a plurality of first conductive type semiconductor doped regions 12, a front surface field layer 13, and an anti-reflection layer 14.

The substrate body 11 has a front side 111, a back side 112, and a textured surface 113. The back side 112 is opposite to the front side 111. The textured surface 113 is formed on the front side 111. The substrate body 11 may be a silicon substrate, which is doped with a first conductive type semiconductor of a first doping concentration. The first conductive type semiconductor is the P-type semiconductor selected from the IIA group or IIIA group elements on the period table or the N-type semiconductor selected from the VA group or VIA group elements on the period table. That is, the substrate body 11 can be a P-type silicon substrate or a N-type silicon substrate. In the present embodiment, the substrate body 11 is a N-type silicon substrate. In addition, the textured surface 113 on the front side 111 of the substrate body 11 may be fabricated by using the process of layer grooving, mechanical surface grooving, or chemical etching.

The first conductive type semiconductor doped regions 12 with a first conductive type semiconductor of a second doping concentration are spaced apart and formed on the back side 112. The first conductive type semiconductor doped regions 12 may be formed on the back side 112 by using the process such as thermal diffusion or ion implantation to have the first conductive type semiconductor entering the back side 112 of the substrate body 11.

The front surface field layer 13 is formed on the front side 111, and the front surface field layer 13 is doped with a first conductive type semiconductor of a third doping concentration which is greater than the first doping concentration. The front surface field layer 13 may be formed on the front side 111 by using the process such as thermal diffusion or ion implantation to introduce the first conductive type semiconductor into the front side 111 of the substrate body 11.

The anti-reflection layer 14 is formed on the front surface field layer 13. The anti-reflection layer 14 is formed on the front surface field layer 13 by using the process such as vacuum coating, chemical vapor deposition (CVD), sol-gel, and etc. to have the material such as SiN and TiO2 formed on the front surface field layer 13 to reduce reflection of the light.

The intrinsic layer 2 is formed on the back side 112, in this embodiment, the intrinsic layer 2 is formed by deposition. The intrinsic layer 2 has a plurality of first openings 21. The first conductive type semiconductor doped regions 12 are exposed from the first openings 21, and the area size of the first opening 21 is smaller than the area size of respective first conductive type semiconductor doped region 12, i.e., the intrinsic layer 2 merely covers the boundary of the first conductive type semiconductor doped region 12 and the central portion of the first conductive type semiconductor doped region 12 is exposed from the first opening 21. The intrinsic layer 2 may be an amorphous silicon intrinsic layer or a microcrystal silicon intrinsic layer. In the present embodiment, the intrinsic layer 2 is an amorphous silicon intrinsic layer formed on the back side 112 by using chemical vapor deposition (CVD) process to deposit amorphous silicon (a-Si:H) on the back side 112. However, in the other embodiment, a microcrystal silicon intrinsic layer with microcrystal silicon (μc-Si) structure can be formed by modulating the parameters of the CVD process. In addition, the first opening 21 is formed by using the process such as etching or laser ablation after the formation of the intrinsic layer 2.

The second conductive type semiconductor layer 3 is formed by depositing a second conductive type semiconductor on the intrinsic layer 2. The intrinsic layer 2 is interposed between the second conductive type semiconductor layer 3 and the first conductive type semiconductor doped region 12, i.e., the intrinsic layer 2 is interposed between the second conductive type semiconductor layer 3 and the substrate body 11. In the present embodiment, the substrate body 11 is an N-type silicon substrate, the second conductive type semiconductor layer 3 is a P-type semiconductor layer. Thus, the intrinsic layer 2 and the substrate body 11 and the second conductive type semiconductor layer 3 compose a p-i-n hetero-junction, which can reduce the interface defects so as to enhance the conversion efficiency of the solar cell. In addition, the second conductive type semiconductor layer 3 has a plurality of second openings 31 corresponding to the first openings 21. The width of the second opening 31 is not smaller than that of the first opening 21, and the second opening 31 is located right above the corresponding first opening 21. As shown in FIG. 3, in the present embodiment, the width of the second opening 31 is greater than that of the first opening 21. However, in the other embodiment, the width of the second opening 31 may be the same as that of the corresponding first opening 21.

Moreover, the second conductive type semiconductor layer 3 may be an amorphous silicon second conductive type semiconductor layer or a microcrystal silicon second conductive type semiconductor layer. In the present embodiment, a CVD process is carried out to form an amorphous silicon second conductive type semiconductor layer doped with second conductive type semiconductor on the intrinsic layer 2 as the second conductive type semiconductor layer 3, and then the second openings 31 are formed by using the process such as etching or laser ablation. However, in the other embodiment, the first openings 21 and the second openings 31 may be formed by using the process such as etching or laser ablation after the formation of the intrinsic layer 2 and the second conductive type semiconductor layer 3; or the intrinsic layer 2 with the first openings 21 and the second conductive type semiconductor layer 3 with the second openings 31 can be directly formed by using the mask.

The electrode layer 4 includes a plurality of first electrode regions 41 and a plurality of second electrode regions 42. The first electrode regions 41 are located on the first conductive type semiconductor doped regions 12 and electrically connected to the first conductive type semiconductor doped regions 12 through the first openings 21 respectively. Because the width of the second opening 31 is greater than that of the first opening 21 and the first electrode region 41, so a gap is formed between the edge of the second opening 31 and the edge of the first electrode region 41, that means the first electrode region 41 could be separated from the second conductive type semiconductor layer 3 to prevent short circuit.

The second electrode regions 42 are spaced apart from each other and located on the second conductive type semiconductor layer 3, and are separated from the first electrode regions 41.

As mentioned above, the back contact solar cell 100 provided in the present invention has the intrinsic layer 2 and the second conductive type semiconductor layer 3 formed on the back side 111 of the substrate body 11 and has the first conductive type semiconductor doped regions 12 exposed from the first openings 21 of the intrinsic layer 2 and the second openings 31 of the second conductive type semiconductor layer 3 so as to have the first electrode regions 41 and the second electrode regions 42 electrically connect the first conductive type semiconductor doped region 12 and the second conductive type semiconductor layer 3 respectively. Because the present embodiment adopts CVD process to form the intrinsic layer 2 and the second conductive type semiconductor layer 3 on the intrinsic layer 2, in compared with the prior art, the processing time can be reduced and it can be performed in low temperature environment. Therefore, the problems such as the generation of the high defect density surface layer due to thermal diffusion of IIIA group elements such as Boron and the difficulty of passivation treatment is prevented.

Moreover, in the present embodiment, the area size of the first conductive type semiconductor doped region 12 exposed from the first opening 21 is smaller than 50% of the overall area size of the first conductive type semiconductor doped region 12. That means more than 50% of the first conductive type semiconductor doped region 12 is covered by the intrinsic layer 2, and the passivation effect would be generated on the first conductive type semiconductor doped region 12 because of the intrinsic layer 2 covering the first conductive type semiconductor doped region 12. In addition, because the first electrode region 41 is in direct contact with the first conductive type semiconductor doped region 12, contact resistance can be reduced to improve power loss. Moreover, the first conductive type semiconductor doped region 12 formed in the surface layer of the substrate body 11 directly will form a back surface field to further enhance output current and voltage.

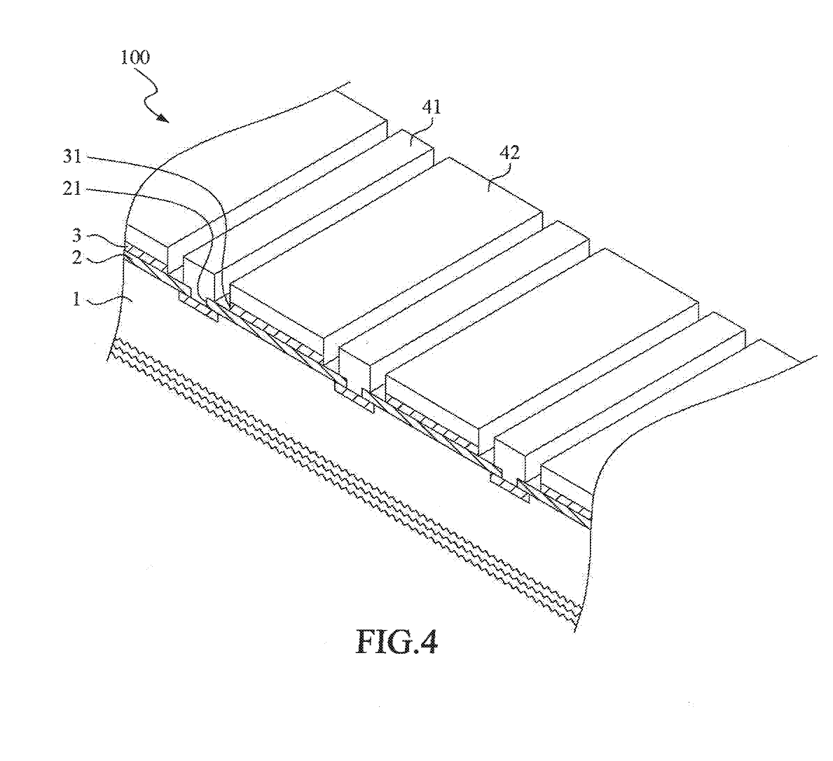

Please refer to FIG. 3 and FIG. 4, wherein FIG. 4 is a 3D cross-section view of a back contact solar cell in accordance with the first preferred embodiment of the present invention. As shown, both the first opening 21 and the second opening 31 are strip type linear openings and the width of the second opening 31 is wider than the width of the first opening 21, such that the first electrode regions 41 formed on the first conductive type semiconductor doped region 12 through the first openings 21 and the second electrode regions 42 on the second conductive type semiconductor layer 3 are alternatively arranged.

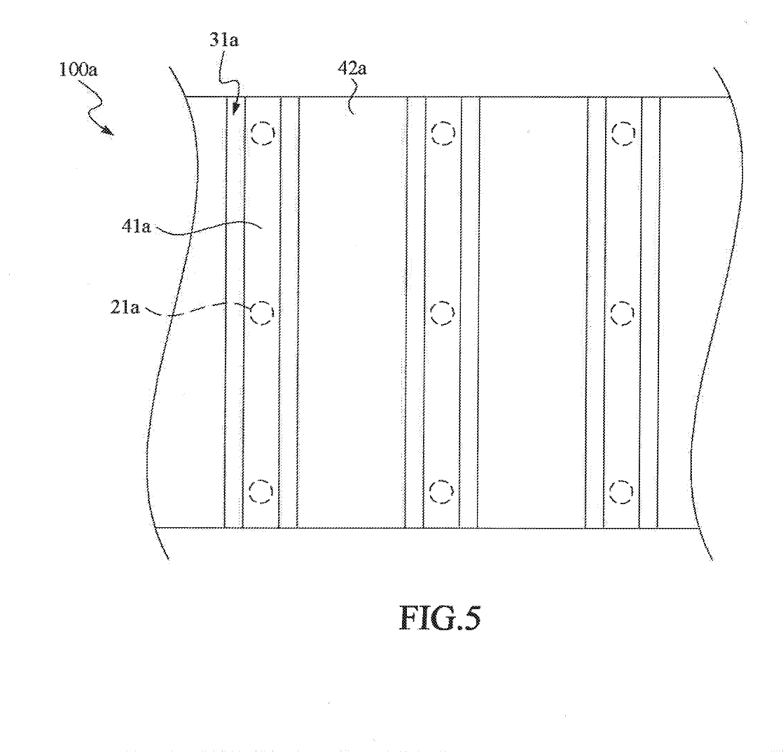

FIG. 5 is a top view of a back contact solar cell in accordance with a second preferred embodiment of the present invention. As shown, the back contact solar cell 100a is similar to the back contact solar cell 100 described in the first preferred embodiment. The only difference is that the first opening 21a of the back contact solar cell 100a is circular in shape and the second opening 31a is a strip type linear opening. In the present embodiment, the width of the first opening 21a can be regarded as the diameter of the first opening 21a because the first opening 21a is circular in shape, such that the width of the second opening 31a being greater than the width of the first opening 21a can be understood as greater than the diameter of the first opening 21a. The first electrode region 41a and the second electrode region 42a of the present embodiment are both of strip type structure. The first electrode region 41a is electrically connected to the first conductive type semiconductor doped region (not shown in FIG. 5) through the circular shaped first opening 21a.

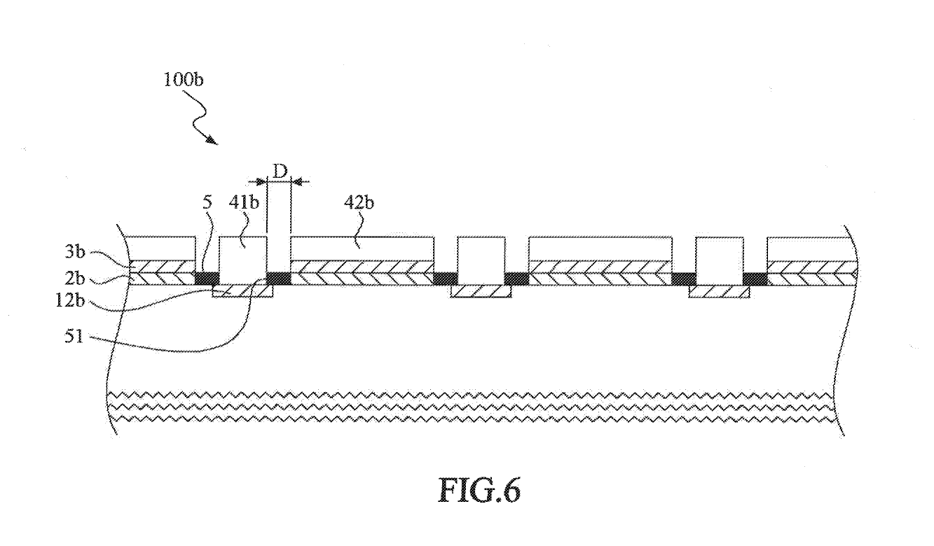

FIG. 6 is a cross-section view showing a back contact solar cell in accordance with a third preferred embodiment of the present invention. As shown, the back contact solar cell 100b is similar to the back contact solar cell 100 described in the first preferred embodiment. The only difference is that the intrinsic layer 2, the second conductive type semiconductor layer 3, the plurality of first electrode regions 41 and the plurality of second electrode regions 42 of the first preferred embodiment are replaced by an intrinsic layer 2b, a second conductive type semiconductor layer 3b, a plurality of first electrode regions 41b, and a plurality of second electrode regions 42b of the back contact solar cell 100b. The width of the second opening of the second conductive type semiconductor layer 3b is equal to that of the respective first opening of the intrinsic layer 2b such that the first electrode region 41b and the intrinsic layer 2b are separated by a gap D and the second conductive type semiconductor layer 3b and the second electrode region 42b are also separated from the first electrode region 41b by the gap 0, thus, short circuit between the first electrode region 41b from contacting the second conductive type semiconductor layer 3b would not occur.

In addition, in compared with the back contact solar cell 100, the back contact solar cell 100b of the present embodiment further comprises a plurality of passivation layers 5, which is formed in the first opening (not labeled) of the intrinsic layer 2b by using CVD process. However, the present invention is not limited. Each of the passivation layers 5 also has a third opening 51. The first conductive type semiconductor doped region 12b is partially covered by the passivation layer 5 such that a portion of the first conductive type semiconductor doped region 12b is exposed from the third opening 51 of the passivation layer 5. That is, the passivation layer 5 is formed in the gap D between the intrinsic layer 2b and the first electrode region 41b to effectively insulate the intrinsic layer 2b and the first electrode region 41b and prevent the current directly flowing between the first electrode region 41b and the second electrode region 42b through the intrinsic layer 2b and the short circuit phenomenon can be eliminated. In the present embodiment, the passivation layer 5 is composed of silicon oxide, which has a better passivation effect for the first conductive type semiconductor doped region 12 than the amorphous silicon intrinsic layer 2b. However, in the other embodiments, the passivation layer 5 may be composed of silicon nitride or other insulation materials. In addition, the passivation layer 5 may be formed in the first opening after the formation of the first opening of the intrinsic layer 2b and before the formation of the second conductive type semiconductor layer 3b, the plurality of first electrode regions 41b and the plurality of second electrode regions 42b, or the passivation layer 5 can be formed in the first opening after the formation of the first opening and the second opening of the intrinsic layer 2b and the second conductive type semiconductor layer 3b and before the formation of the first electrode region 41b.

The area size of the first opening of the intrinsic layer 2b of the present embodiment is greater than the area size of the first conductive type semiconductor doped region 12b. The passivation layer 5 covers a portion of the first conductive type semiconductor doped region 12b. However, in the other embodiment, the first electrode region 41b covers the whole first conductive type semiconductor doped region 12b such that the passivation layer 5 does not cover any portion of the first conductive type semiconductor doped region 12b.

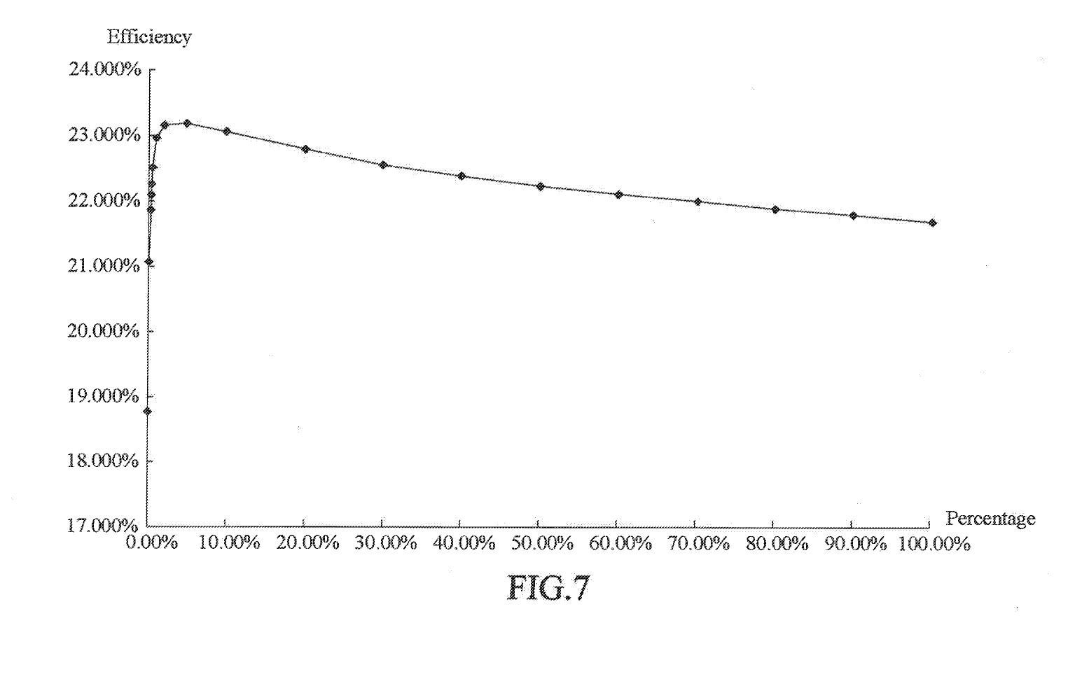

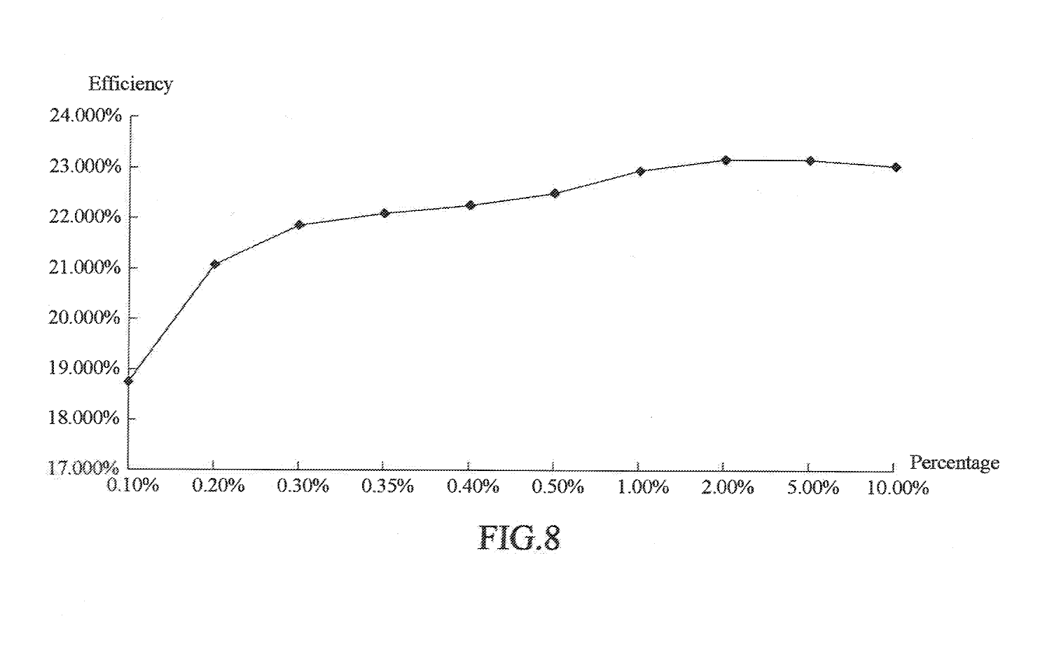

Please refer to FIG. 7, FIG. 8 and the following table 1, wherein FIG. 7 is a diagram showing the relationship of conversion efficiency of the back contact solar cell of the present invention and the opening size by percentage, FIG. 8 is a diagram showing the relationship of conversion efficiency of the back contact solar cell of the present invention and the opening size by percentage as the percentage is from 0.1% to 10%. According to the experimental result as shown in FIG. 7, FIG. 8, and table 1, the conversion efficiency is improved significantly when the percentage of the first opening in the intrinsic layer of area size of the first conductive type doped region in the first preferred embodiment and the second preferred embodiment, or the third opening in the passivation layer in the third preferred embodiment of area size of the first conductive type semiconductor doped region, is greater than 0.20%. That is, if there exists an opening on the first conductive type semiconductor doped region, which is at least 0.20% of the area size of the first conductive type semiconductor doped region, the first electrode is capable to electrically couple the first conductive type semiconductor doped region through the opening to reduce the resistance therebetween and enhance the conversion efficiency. If there exists an opening with the area size is from 0.35% to 70% of the area size of the first conductive type semiconductor doped region, the conversion efficiency of the back contact solar cell may achieve a higher level. Generally, the present invention is capable to avoid the problems when the opening size in the intrinsic layer and/or the passivation layer is too large to result in a reduced passivation effect and when the opening size is too small to result in an high resistance, such that the back contact solar cell provided in the present invention can access a good passivation effect and conversion efficiency.

TABLE 1

| Exp. | Percentage | Efficiency |
|---|---|---|
| 1 | 0.10% | 18.77% |
| 2 | 0.20% | 21.08% |
| 3 | 0.30% | 21.87% |
| 4 | 0.35% | 22.10% |
| 5 | 0.40% | 22.27% |
| 6 | 0.50% | 22.50% |
| 7 | 1.00% | 22.96% |
| 8 | 2.00% | 23.16% |
| 9 | 5.00% | 23.18% |
| 10 | 10.00% | 23.04% |
| 11 | 20.00% | 22.78% |
| 12 | 30.00% | 22.56% |
| 13 | 40.00% | 22.38% |
| 14 | 50.00% | 22.23% |
| 15 | 60.00% | 22.10% |
| 16 | 70.00% | 22.00% |
| 17 | 80.00% | 21.88% |
| 18 | 90.00% | 21.79% |
| 19 | 100.00% | 21.70% |

Besides, the substrate body and the back side of the back contact solar cell of the present invention are of the same conductive type, which may be of P-type or N-type. If the first conductive type semiconductor in the substrate body and the first conductive type semiconductor doped regions on the back side of the substrate body are both N-type, high defect density boron rich layer (BRL) due to the long time thermal diffusion process of Boron in the high temperature furnace of the traditional interdigitated back contact (IBC) solar cell can be eliminated which means that the present invention is capable to prevent the formation of high defect density BRL and further reduce the surface defects on the back side of the back contact solar cell to enhance conversion efficiency.

The detail description of the aforementioned preferred embodiments is for clarifying the feature and the spirit of the present invention. The present invention should not be limited by any of the exemplary embodiments described herein, but should be defined only in accordance with the following claims and their equivalents. Specifically, those skilled in the art should appreciate that they can readily use the disclosed conception and specific embodiments as a basis for designing or modifying other structures for carrying out the same purposes of the present invention without departing from the scope of the invention as defined by the appended claims.

What is claimed is:

1. A back contact solar cell, comprising:
a solar cell substrate, including:
a substrate body, having a front side and a back side opposite to the front side, and doped with a first conductive type semiconductor of a first doping concentration; and
a plurality of first conductive type semiconductor doped regions, spaced apart and formed on the back side of the substrate body, doped with the first conductive type semiconductor of a second doping concentration, and the second doping concentration being greater than the first doping concentration;
an intrinsic layer, formed on the back side of the substrate body and on the first conductive type semiconductor doped regions, wherein the intrinsic layer has a plurality of first openings to expose the first conductive type semiconductor doped regions;
a second conductive type semiconductor layer, formed on the intrinsic layer, and having a plurality of second openings corresponding to the first openings, and a width of the second opening being not smaller than that of the corresponding first opening; and
an electrode layer, including:
a plurality of first electrode regions, electrically connected to the first conductive type semiconductor doped region through the first openings and separated from the second conductive type semiconductor layer; and
a plurality of second electrode regions, spaced apart and formed on the second conductive type semiconductor layers and separated from the first electrode regions.

2. The back contact solar cell of claim 1, wherein the area size of the first openings is not greater than the area size of the first conductive type semiconductor doped regions.

3. The back contact solar cell of claim 2, wherein the area size of the first opening is from 0.2% to 100% of the area size of the first conductive type semiconductor doped region.

4. The back contact solar cell of claim 3, wherein the area size of the first opening is from 0.35% to 70% of the area size of the first conductive type semiconductor doped region.

5. The back contact solar cell of claim 1, wherein the area size of the first openings is greater than the area size of the first conductive type semiconductor doped regions.

6. The back contact solar cell of claim 5, further comprising a plurality of passivation layers formed in the first openings respectively, each of the passivation layers having a third opening, the first electrode regions electrically connected to the first conductive type semiconductor doped regions through the third openings respectively, and area size of the third openings being not greater than area size of the first conductive type semiconductor doped regions.

7. The back contact solar cell of claim 6, wherein the third openings are formed in a circular shape, a strip shape, or a combination thereof.

8. The back contact solar cell of claim 6, wherein the area size of the third opening is from 0.2% to 100% of the area size of the first conductive type semiconductor doped region.

9. The back contact solar cell of claim 8, wherein the area size of the third opening is from 0.35% to 70% of the area size of the first conductive type semiconductor doped region.

10. The back contact solar cell of claim 5, wherein the first electrode regions and the intrinsic layers are separated by a gap, and the back contact solar cell further comprises a plurality of passivation layers deposited in the gap.

11. The back contact solar cell of claim 1, wherein the solar cell substrate further comprises a front surface field layer, formed on the front side.

12. The back contact solar cell of claim 11, wherein the front surface field layer is doped with the first conductive type semiconductor of a third doping concentration, which is greater than the first doping concentration.

13. The back contact solar cell of claim 11, further comprising an anti-reflection layer, formed on the front surface field layer.

14. The back contact solar cell of claim 1, wherein the substrate body has a textured surface on the front side.

15. The back contact solar cell of claim 1, wherein the first openings are formed in a circular shape, a strip shape, or a combination thereof.

16. The back contact solar cell of claim 1, wherein the second openings are formed in a strip shape.

17. The back contact solar cell of claim 1, wherein the intrinsic layer is an amorphous silicon intrinsic layer or a microcrystal silicon intrinsic layer.

18. The back contact solar cell of claim 1, wherein the second conductive type semiconductor layer is an amorphous silicon second conductive type semiconductor layer or a microcrystal silicon second conductive type semiconductor layer.
